(19) United States
(12) Patent Application Publication
(10) Pub. No.: US 2005/0088239 A1
(43) Pub. Date: Apr. 28, 2005

(54) Short-circuit detecting and protecting circuit for integrated circuit

(76) Inventor: Jy-Der David Tai, Phoenix, AZ (US)

Correspondence Address: CHARLES E. BAXLEY, ESQUIRE, Third Floor, 90 John Street, New York, NY, 10038, US

(21) Appl. No.: 10/693,093

(22) Filed: Oct. 23, 2003

(51) Int. Cl. H03F 1/52

(52) U.S. Cl. 330/298

(57) ABSTRACT

A short-circuit detecting and protecting circuit includes a switching unit for obtaining input signals, a comparator having one input terminal coupled to the switching unit, a control transistor coupled between the switching unit and the other input terminal of the comparator to define input time of the input signals. A circuit may be used to detect a voltage difference between the input terminals of the comparator. The comparator may compare the voltage difference between the input terminals of the comparator and internal voltage of the comparator, to determine a short-circuit or overload situation.

### BACKGROUND OF THE INVENTION

1. Field of the Invention

The present invention relates to a short-circuit or overcurrent detecting and protecting circuit, and more particularly to a short-circuit or overcurrent detecting and protecting circuit for integrated circuits where high electric current may flow therethrough.

2. Description of the Prior Art

Typical integrated circuits may have overcurrent or overload situations or problems occurred frequently. One of the mostly occurred reasons is that the typical integrated circuits themselves are short-circuited. The other reason is that high electric currents may flow through the typical integrated circuits which have low resistance load.

For example, when two or more high drivability terminals of the typical integrated circuits are contacted or coupled together, or are directly coupled to the electric power sources, and include different voltages in these terminals or sources, the instant electric current flowing through the typical integrated circuits may overload or may exceed the predetermined safety range.

Normally, the resistance of a power driver in the typical integrated circuits is low, and the typical integrated circuits may thus be short-circuited and damaged when the instant electric current exceeds the predetermined safety range and flows through the typical integrated circuits. Several patents have been developed to protect the typical integrated circuits to prevent the typical integrated circuits from damage during short-circuited or overloaded.

For example, U.S. Pat. No. 5,973,569 to Nguyen discloses a short-circuit protection and overcurrent modulation which employs a known resistance to fetch or obtain a voltage signal, and a bandgap reference circuit to generate a reference voltage, and a comparator circuit to compare the voltage signal and the reference voltage, and to detect whether the voltage signal is abnormal or not.

The detecting voltage is arranged to be generated by a current mirror. However, the gate voltages of the transistors are the switching voltages generated by the pulse-width modulator (PWM) that has little current mirror effect, and that may not reach the tracking effect. In addition, the bandgap reference circuit will increase the manufacturing cost.

U.S. Pat. No. 6,108,182 to Pullen discloses an overcurrent sensing circuit and self adjusting blanking which includes two resistors to convert electric power to high voltages, and a current mirror formed by bipolar transistors and metal oxide semiconductor type field effect transistor (MOSFET) to fetch and obtain two currents, and to compare the currents with a reference voltage signal (3.5V), in order to actuate a protective circuit when overload situation is generated or occurred.

However, the overcurrent sensing circuit requires bipolar transistors that require a stabilized voltage difference Vbe (about 0.6V) between the base and the emitter thereof. In addition, the overcurrent sensing circuit requires a reference signal (3.5V) that increases the manufacturing cost. Furthermore, the overcurrent sensing circuit may not be manufactured with a metal oxide semiconductor (MOS) manufacturing process.

The present invention has arisen to mitigate and/or obviate the afore-described disadvantages of the conventional short-circuit detecting and protecting devices.

### SUMMARY OF THE INVENTION

The primary objective of the present invention is to provide a short-circuit detecting and protecting circuit for integrated circuits where high electric current may flow therethrough.

In accordance with one aspect of the invention, there is provided a short-circuit detecting and protecting circuit comprising a switching unit for obtaining input signals, a comparator including a first input terminal coupled to the switching unit, an output terminal, and a second input terminal, and including an internal voltage, a control transistor coupled between the switching unit and the second input terminal of the comparator, to define input time of the input signals, and means for detecting a voltage difference between the first and the second input terminal of the comparator. The comparator may compare the voltage difference between the first and the second input terminal of the comparator and internal voltage of the comparator, to determine a short-circuit or overload situation.

The switching unit includes a first transistor coupled to the first input terminal of the comparator and obtains one of the input signals, and a second transistor coupled to the control transistor and obtains the other input signal. The switching unit is preferably a complementary metallic oxide semiconductor (CMOS) having a pMOS and an nMOS.

The detecting means includes a detecting resistor coupled between the first and the second input terminals of the comparator, to generate and provide two voltage signals to the first and the second input terminals of the comparator respectively.

A divider resistor may further be provided and coupled between the control transistor and the second input terminal of the comparator, to divide the input signals. A load resistor further be provided and coupled to the first input terminal of the comparator and grounded.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a plan schematic view of a short-circuit detecting and protecting circuit in accordance with the present invention;

FIG. 2 is a diagram illustrating the operation procedures of the short-circuit detecting and protecting circuit;

FIG. 3 is a plan schematic view similar to FIG. 1, illustrating the actuation of the short-circuit detecting and protecting circuit with different actuating signals;

FIG. 4 is a diagram similar to FIG. 2, illustrating the operation procedures of the short-circuit detecting and protecting circuit as shown in FIG. 3;

FIG. 5 is a plan schematic view, illustrating the embodiment of the present invention combined by the short-circuit detecting and protecting circuits as shown in FIGS. 1 and 3, and to be actuated with corresponding actuating signals;

FIG. 6 is a plan schematic view similar to FIG. 5, illustrating the further embodiment of the present invention actuatable with corresponding actuating signals;

FIG. 7 is a plan schematic view of detecting circuit to simplify the schematic view of FIG. 8; and

FIG. 8 is a plan schematic view similar to FIG. 5, illustrating the other embodiment of the present invention.

### DETAILED DESCRIPTION OF THE PREFERRED EMBODIMENT

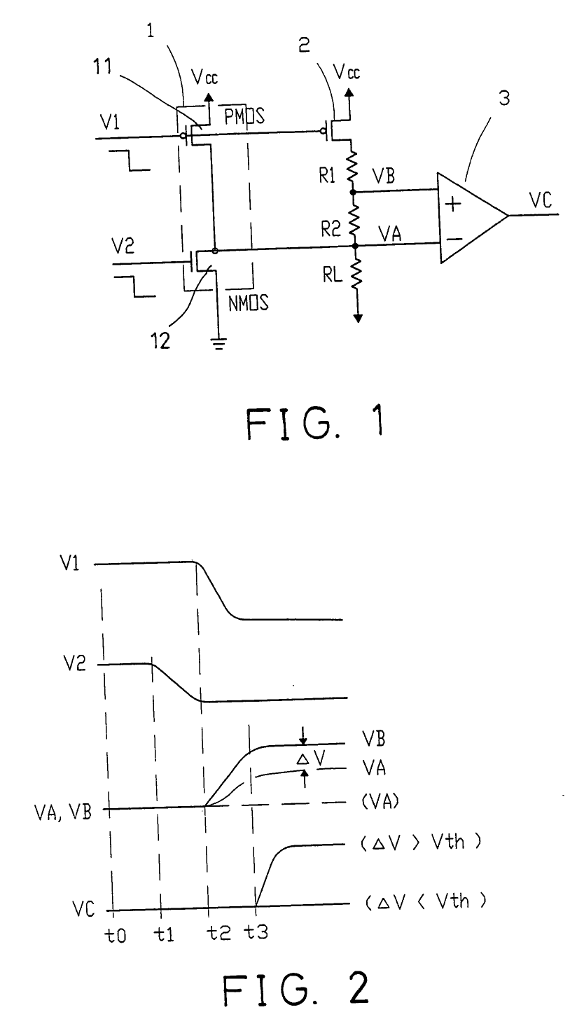

Referring to the drawings, and initially to FIGS. 1 and 2, a short-circuit detecting and protecting circuit in accordance with the present invention comprises a switching unit 1 including a complementary metallic oxide semiconductor (CMOS) having two switching transistors 11, 12, such as a pMOS 11 and an nMOS 12.

For example, as shown in FIG. 1, the drain electrodes of the switching transistors pMOS 11 and nMOS 12 are connected together, the source electrode of the switching transistor pMOS 11 is coupled to electric power source Vcc, and the source electrode of the other switching transistor nMOS 12 is grounded. The transistors pMOS 11 and nMOS 12 are arranged to fetch or obtain input signals V1 and V2 via the gate electrodes thereof.

A control transistor 2 is preferable a pMOS (low voltage actuated), and includes a source electrode coupled to electric power source Vcc, and a gate electrode coupled to the gate electrode of the pMOS 11, and a drain electrode coupled to a positive input of a comparator 3 via a divider resistor R1. A detecting resistor R2 is coupled between the positive and negative inputs of the comparator 3, to form or provide input voltage signals VB and VA to the positive and negative inputs of the comparator 3 respectively.

The negative input of the comparator 3 is grounded via a load resistor RL, and is coupled to the output terminal of the switching unit 1, or coupled to the drain electrode of the transistor nMOS 12. The comparator 3 may compare the input voltage signals VB and VA, and generate an output voltage VC, which may be used to detect or to know whether an abnormal condition occurs by overloading or short-circuit.

As shown in FIG. 2, when the input signals V1 and V2 are high voltage signals between times t0-t1, both the pMOS 12 of the switching unit 1 and the control transistor 2 are at the switch-off situation, such that no electric current will flow through both the divider resistor R1 and the detecting resistor R2, the voltage difference of VA and VB at the ends of the detecting resistor R2 will be zero, and thus the output voltage VC of the comparator 3 will be at a low status.

When the input signal V2 is dropped or decreased from high voltage to low voltage between times t1-t2, the input voltages VA and VB of the comparator 3 are remain controlled by the control transistor 2. At this moment, due to the switching off situation of the control transistor 2, the input voltages VA and VB of the comparator 3 will both be zero, and thus the output voltage VC of the comparator 3 will also be maintained at the low status.

When the other input signal V1 is also dropped or decreased from high voltage to low voltage between times t2-t3; i.e., both the input signals V1, V2 will be the low voltage signals, both the pMOS 11 of the switching unit 1 and the control transistor 2 will be actuated or energized and will be at the switch-on situation, such that electric current will flow from the electric power source Vcc through both the source and the drain electrodes of the control transistor 2, and then flow to the ground via the divider resistor R1 and the detecting resistor R2 and the load resistor RL. The transistor nMOS 12 is in off state and no current flows through this transistor.

At this moment, when the load resistor RL has a too small resistance, or when a short-to-ground situation is generated in the output terminal of the switching unit 1, the electric current flowing through the divider resistor R1 and the detecting resistor R2, the current may exceed or may be greater than the normal current flow, and may generate a voltage difference ΔV (VB−VA) which may be greater than the internal or predetermined voltage Vth in or of the comparator 3.

As also shown in FIG. 2, when the voltage difference ΔV (VB−VA) is greater than the internal voltage Vth in or of the comparator 3, the output terminal of the comparator 3 may output a high output voltage VC at the time that is greater than t3, such that the overload or overcurrent or short-circuit situation may be detected. On the contrary, if RL resistance is not small enough or the current is not high enough the voltage difference ΔV (VB−VA) is smaller than the internal voltage Vth in the comparator 3, the output terminal of the comparator 3 may still be maintained at the low status.

It is to be noted that the control transistor 2 is a low voltage actuated transistor pMOS, and includes a low resistance while switching on or while being energized, the electric power Vcc is dropped across the divider resistor R1, the detecting resistor R2 and the load resistor RL. The divider resistor R1 and the detecting resistor R2 may proportionally divide the voltage for a given RL resistance, such that the detecting operation may be ascertained or confirmed.

The control transistor 2 may thus be used as an actuating device or means to determine or define the timing or the times t0, t1, t2, t3 when the signals input to the short-circuit detecting and protecting circuit in accordance with the present invention.

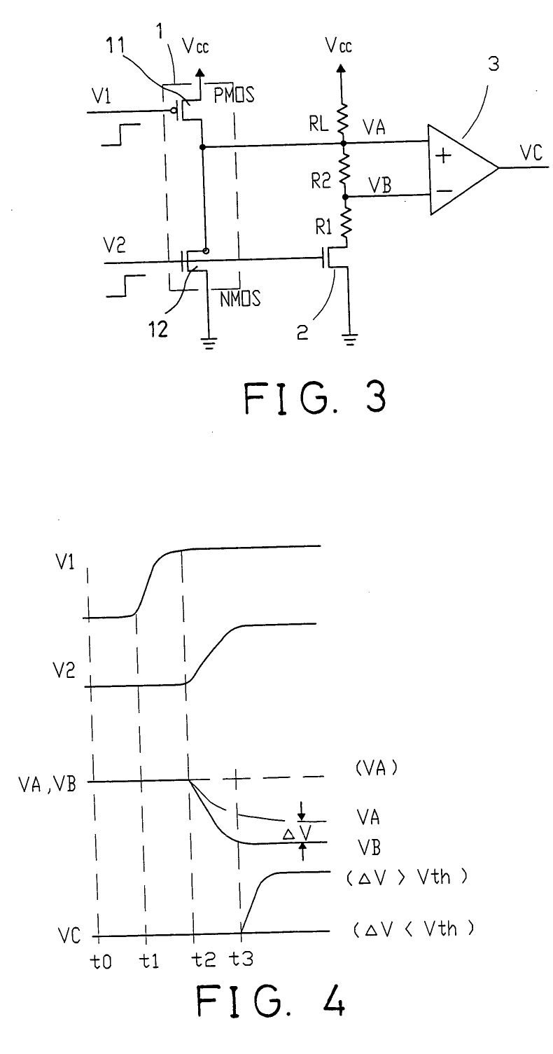

Referring next to FIGS. 3 and 4, illustrated is a switching unit 1 having two transistors pMOS 11 and nMOS 12 arranged to fetch or obtain input signals V1 and V2 via the gate electrodes thereof. The control transistor 2 is preferable an nMOS (high voltage actuated), and includes a source electrode grounded, and a gate electrode coupled to the gate electrode of the nMOS 12, and a drain electrode coupled to a negative input of the comparator 3 via a divider resistor R1. A detecting resistor R2 is coupled between the positive and negative inputs of the comparator 3, to form or provide input voltage signals VA and VB to the positive and negative inputs of the comparator 3 respectively.

The positive input of the comparator 3 is coupled to electric power source Vcc via a load resistor RL, and is coupled to the output terminal of the switching unit 1, or coupled to the drain electrode of the transistor pMOS 11. The comparator 3 may compare the input voltage signals VA and VB, and generate an output voltage VC, which may be used to detect or to know whether an abnormal condition occurs by overloading or short-circuit.

As shown in FIG. 4, when the input signals V1 and V2 are low voltage signals between times t0-t1, and/or when the input signal V1 is increased from low voltage to high voltage between times t1-t2, the control transistor 2 is at the switch-off situation, such that no electric current will flow through both the divider resistor R1 and the detecting resistor R2, the voltage difference of VA and VB at the ends of the detecting resistor R2 will be zero, and thus the output voltage VC of the comparator 3 will be at a low status.

When the other input signal V2 is also increased from low voltage to high voltage between times t2-t3; i.e., both the input signals V1, V2 will be the high voltage signals, both the nMOS 12 of the switching unit 1 and the control transistor 2 will be actuated or energized and will be at the switch-on situation, such that electric current will flow from the electric power source Vcc through the load resistor RL, the detecting resistor R2, the divider resistor R1, and then flow to the ground via the source and the drain electrodes of the control transistor 2.

At this moment, when the load resistor RL has a too small resistance, or when a short-to-Vcc situation is generated in the output terminal of the switching unit 1, the electric current flowing through the divider resistor R1 and the detecting resistor R2, the current may exceed or may be greater than the normal current flow, and may generate a voltage difference ΔV (VA−VB) which may be greater than the internal voltage Vth in the comparator 3.

As also shown in FIG. 4, when the voltage difference ΔV (VA−VB) is greater than the internal voltage Vth in the comparator 3, the output terminal of the comparator 3 may output a high output voltage VC at the time that is greater than t3, such that the overload or overcurrent or short-circuit situation may be detected. On the contrary, if RL resistance is not small enough or the current is not big enough the voltage difference ΔV (VA−VB) is smaller than the internal voltage Vth in the comparator 3, the output terminal of the comparator 3 may still be maintained at the low status.

It is to be noted that the control transistor 2 is a high voltage actuated transistor nMOS, and includes a low resistance while switching on or while being energized, the electric power Vcc is dropped across the load resistor RL, the detecting resistor R2 and the divider resistor R1. The divider resistor R1 and the detecting resistor R2 may proportionally divide the voltage for a given RL resistance, such that the detecting operation may be ascertained or confirmed.

It is to be noted that the divider resistor R1 and the detecting resistor R2 may proportionally divide the voltage, such that the detecting operation may be ascertained or confirmed. No expensive reference signal circuit is required, and thus the manufacturing cost thereof may be greatly decreased. The voltage difference at the ends of the detecting resistor R2 are directly compared with the internal voltage Vth in the comparator, and are not required to be compared with the electric power source Vcc or ground or a regulated reference voltage.

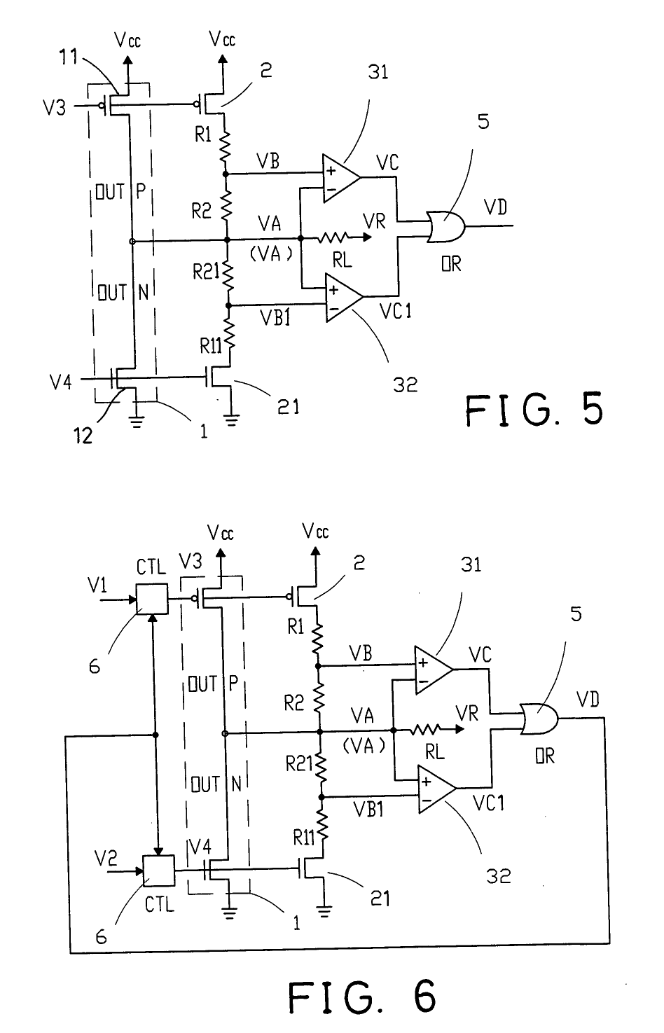

Referring next to FIG. 5, illustrated is a short-circuit or overcurrent detecting and protecting circuit combined by the devices shown in FIGS. 1 and 3. The gate electrode of the switching transistor pMOS 11 is coupled to the gate electrode of the control transistor pMOS 2, and arranged to receive the input signal V3, the drain electrode of the control transistor pMOS 2 is coupled to the positive input of the comparator 31 via a divider resistor R1, to form or provide an input voltage signal VB to the positive input of the comparator 31. The source electrode of the trigger control transistor pMOS 2 is coupled to electric power source Vcc.

The gate electrode of the switching transistor nMOS 12 is coupled to the gate electrode of the control transistor nMOS 21, and arranged to receive the input signal V4, the drain electrode of the control transistor nMOS 21 is coupled to the negative input of the comparator 32 via a divider resistor R11, to form or provide an input voltage signal VB1 to the negative input of the comparator 32. The source electrode of the control transistor nMOS 21 is grounded.

The positive input of the comparator 31 and the negative input of the comparator 32 are coupled together with two detecting resistors R2, & R21, which are then coupled to the drain electrodes of the transistor pMOS 11 and nMOS 12, and simultaneously coupled to the negative input of the comparator 31 and the positive input of the comparator 32, in order to provide input signals VA to the negative input of the comparator 31 and the positive input of the comparator 32, and simultaneously coupled to a load resistor RL, in order to form or provide or to be coupled to a voltage signal VR.

The output terminals of the comparators 31, 32 are coupled to input terminals of an OR gate 5, for providing input voltage signals VC and VC1 to the OR gate 5.

In operation, when the input voltage signals V3 and V4 are both low or high the difference voltages between VA & VB, or VA & VB1 may be generated via the resistors R2, & R21 and to be greater than that of the internal voltage Vth or Vth1 of the comparators 31 or 32, in order to generate a high output voltage VC or VC 1, and so as to generate a high output voltage VD via the OR gate 5. The circuit as shown in FIG. 5 may thus be used to detect or to know whether an overload or overcurrent or a short-circuit situation occurs between output terminal VA and power source VCC or ground, or if RL resistance is too small in the integrated circuit by either the high or the low voltage signals.

Referring next to FIG. 6, two control circuits CTL 6 may further be provided and coupled between input signals V1 and V3; and V2 and V4 respectively, for overcurrent or overload controlling purposes. The output terminal of the OR gate 5 is coupled between the two control circuits CTL 6 which may simultaneously turned off or switch off the input signals V1 and V2 in order to switch off the switching unit 1 when overcurrent or overload problems occurred, in order to prevent further outwardly flowing electric current, and so as to protect the short-circuit detecting and protecting circuit in accordance with the present invention.

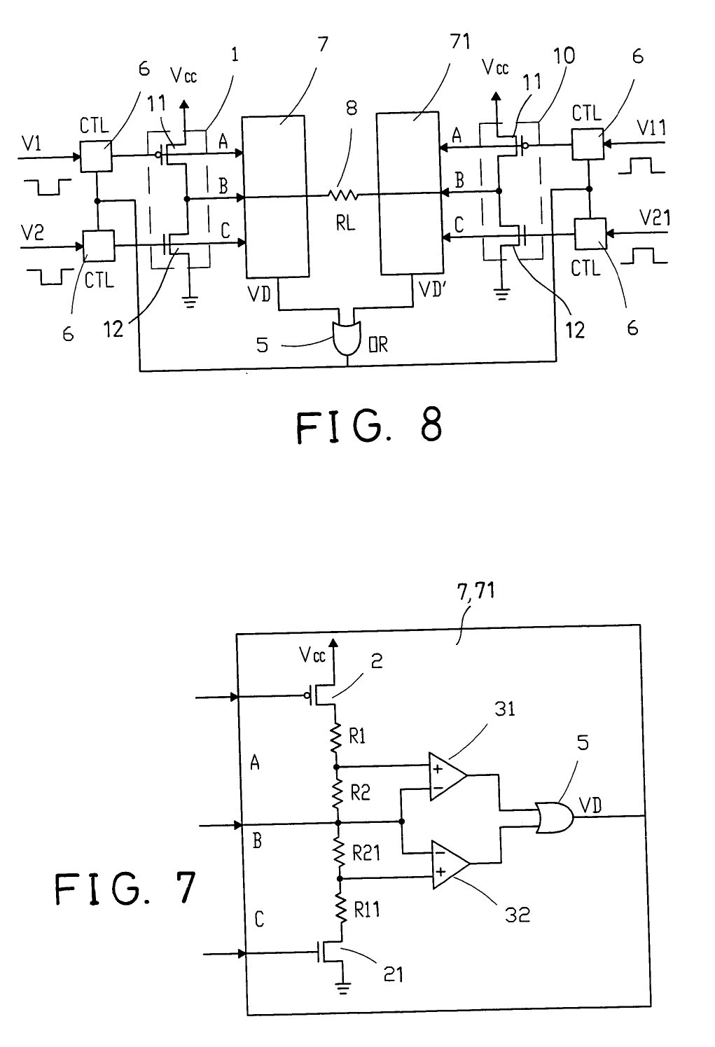

To simplify the explanation for following discussion the detecting circuit is illustrated in FIG. 7 to couple or form the control transistors pMOS 2, & nMOS 21, the resistors R11, R11, R2, R21, and the comparators 31, 32 into a detecting circuit 7 or 71 in FIG. 8.

Referring next to FIG. 8, the short-circuit detecting and protecting circuit may also be coupled in simplified balance-tied load (BTL) type coupling. Two of the detecting circuits 7, 71 may be provided and may have a load RL 8 coupled between the two detecting circuits 7, 71, in order to detect whether the electric current flowing through the load RL 8 is overcurrent or overload or not. The input signals V1 and V2 are in phase, the input signals V11 and V21 are in phase. However, the input signals V1 and V11 are opposite in phase, the input signals V2 and V21 are opposite in phase.

In operation, as shown in FIGS. 7 and 8, when the input signals V1 and V2 are low and the input signals V11 and V21 are high, the transistor pMOS 11 of the switching unit 1 is energized and the other transistor nMOS 12 is switched off. The transistor nMOS 12 of the switching unit 10 is energized and the other transistor pMOS 11 is switched off.

Electric current will thus flow from the electric power Vcc of the switching unit 1, through the transistor pMOS 11 of the switching unit 1, and then through the load RL 8, and then grounded via the transistor nMOS 12 of the switching unit 10. Electric current will also flow through the control transistor 2 of the detecting circuit 7, and then through the resistors R1 and R2, and then grounded via the load RL 8 and the transistor nMOS 12 of the switching unit 10. Electric current will also flow from terminal B of switching unit 10 through R21, R11 and the control transistor 21 of the detecting circuit 71 and then to ground. Since the transistor pMOS 11 of switching unit 1 and the transistor nMOS 12 of switching unit 10 are on, the electric current through detecting circuit 7 and 71 are relatively small. At this moment, the lower resistance of the load RL 8, the larger electric current may flow through RL 8.

When the terminal or point B of detecting unit 7 is short-circuited to ground, large electric current will flow through pMOS 11 of switching unit 1. Larger electric current may also flow from the electric power Vcc through the resistors R1 and R2 of the detecting circuit 7 to ground. In this situation, the voltage drop through the detecting resistor R2 of the detecting circuit 7 is greater than the internal voltage Vth of the comparator 31, such that the comparator 31 may generate and output a high output voltage, and then may output a high output voltage at VD via the OR gate 5.

When the terminal or point B of the detecting circuit 71 is short-circuited to the electric power Vcc, large electric current will flow through transistor nMOS 12 of switching unit 10. The electric current will also flow from electric power Vcc or terminal or point B of the detecting circuit 71, and then through the resistors R21 and R11 of the detecting circuit 71, and then grounded via the drain and source terminals of the control transistor 21 of the detecting circuit 71.

At this moment, the electric current flowing through the resistors R21 and R11 may be greater than the normal current, and an increasing voltage may be generated by the electric current flowing through the resistor R21 of the detecting circuit 71 and may be greater than the internal voltage Vth1 of the comparator 32, such that the comparator 32 may generate and output a high output voltage, and then may output a high output voltage at VD via the OR gate 5, so as to detect the overcurrent or overload conditions.

When the load RL 8 is small, the current flowing through the control transistor 2, the resistors R1 & R2 of the detecting circuit 7 and the resistors R21 and R11 and the control transistor 21 of the detecting circuit 71 will be bigger. The voltage drop across the resistor R2 of the detecting circuit 7 may be greater than the internal voltage of the comparator 31 or the voltage drop across the resistor R2 of the detecting circuit 71 may be greater than the internal voltage of the comparator 32. A high voltage at VD may be generated at VD or VD′ to detect the overcurrent or overload conditions.

On the contrary, when the input signals V1 and V2 are high and the input signals V11 and V21 are low, the transistor pMOS 11 of the switching unit 10 is energized and the other transistor nMOS 12 is switched off. The transistor nMOS 12 of the switching unit 1 is energized and the other transistor pMOS 11 is switched off.

Electric current will thus flow from the electric power Vcc of the switching unit 10, through the transistor pMOS 11 of the switching unit 10, and then through the load RL 8, and then grounded via the transistor nMOS 12 of the switching unit 1. Electric current will also flow through the control transistor 2 of the detecting circuit 71, and then through the resistors R1 and R2, and then grounded via the load RL 8 and the transistor nMOS 12 of the switching unit 1. Electric current will also flow from terminal B of switching unit 1 through R21, R11 and the control transistor 21 of the detecting circuit 7 and then to ground. Since the transistor pMOS 11 of switching unit 10 and the transistor nMOS 12 of switching unit 1 are on, the electric current through detecting circuit 7 and 71 are relatively small. At this moment, the lower resistance of the load RL 8, the larger electric current may flow through RL 8.

When the terminal or point B of the detecting circuit 71 is short-circuited to ground, large electric current may flow through pMOS 11 of switching 10. Larger electric current may also flow from the electric power Vcc through the resistors R1 and R2 of the detecting circuit 71 to ground. In this situation, the voltage drop through the detecting resistor R2 of the detecting circuit 71 is greater than the internal voltage Vth1 of the comparator 31 of the detecting circuit 71, such that the comparator 31 may generate and output a high output voltage, and then may output a high output voltage at VD via the OR gate 5.

When the terminal or point B of the detecting circuit 7 is short-circuited to the electric power Vcc, large electric current will flow from electric power Vcc to ground through transistor nMOS 12 of switching unit 1. Larger electric current will flow from electric power Vcc or the terminal or point B of the detecting circuit 7, through the resistors R21 and R11 of the detecting circuit 7, and then grounded via the drain and source terminals of the control transistor 21 of the detecting circuit 7.

At this moment, the electric current flowing through the resistors R21 and R11 may be greater than the normal current, and an increasing voltage may be generated by the electric current flowing through the resistor R21 of the detecting circuit 7 and may be greater than the internal voltage Vth1 of the comparator 32, such that the comparator 32 may generate and output a high output voltage, and then may output a high output voltage at VD via the OR gate 5, so as to detect the overcurrent or overload conditions.

When the load RL 8 is small, the current flowing through the control transistor 2, the resistors R1 & R2 of the detecting circuit 71 and the resistors R21 and R11 and the control transistor 21 of the detecting circuit 7 will be bigger. The voltage drop across the resistor R2 of the detecting circuit 71 may be greater than the internal voltage of the comparator 31 or the voltage drop across the resistor R2 of the detecting circuit 7 may be greater than the internal voltage of the comparator 32. A high voltage at VD may be generated at VD or VD′ to detect the overcurrent or overload conditions.

Accordingly, either of the comparators 31, 32 of either of the detecting circuits 7, 71 may generate and output a high output voltage whenever an overcurrent or overload or abnormal condition is occurred caused by short circuited to power Vcc or ground or low RL resistance, either of the OR gate 5 of either of the detecting circuits 7, 71 may also generate and output a high output voltage. These high output voltage signals may actuate the control circuits CTL 6 to switch off the input signals V1, V2, V11, V21, in order to switch off all of the transistors of the switching unit 1 and 10 since these transistors draw large currents, and to stop or terminate the overcurrent or overload conditions, and thus to protect the circuit from being damaged.

Accordingly, the short-circuit detecting and protecting circuit in accordance with the present invention may be provided for detecting the overload and/or the overcurrent and/or the short-circuit situation in the integrated circuits, and thus to prevent large electric currents from flowing through the integrated circuits, and thus to protect the integrated circuits from being damaged.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

1. A short-circuit detecting and protecting circuit comprising:
a switching unit for obtaining input signals,
a comparator including a first input terminal coupled to said switching unit, an output terminal, and a second input terminal, and including an internal voltage,
a control transistor coupled between said switching unit and said second input terminal of said comparator, to define input time of the input signals, and
means for detecting a voltage difference between said first and said second input terminal of said comparator,
said comparator comparing the voltage difference between said first and said second input terminal of said comparator and internal voltage of said comparator, to determine a short-circuit or overload situation.

2. The short-circuit detecting and protecting circuit as claimed in claim 1, wherein said switching unit includes a first transistor coupled to said first input terminal of said comparator to obtain one of the input signals, and a second transistor coupled to said control transistor to obtain the other input signal.

3. The short-circuit detecting and protecting circuit as claimed in claim 1, wherein said switching unit is a CMOS having a pMOS and an nMOS.

4. The short-circuit detecting and protecting circuit as claimed in claim 1, wherein said detecting means includes a detecting resistor coupled between said first and said second input terminals of said comparator, to generate and provide two voltage signals to said first and said second input terminals of said comparator respectively.

5. The short-circuit detecting and protecting circuit as claimed in claim 1 further comprising a divider resistor coupled between said control transistor and said second input terminal of said comparator, to divide the signals.

6. The short-circuit detecting and protecting circuit as claimed in claim 1 further comprising a load resistor coupled to said first input terminal of said comparator and ground.

7. A short-circuit detecting and protecting circuit comprising:
a switching unit including a first and a second switching transistors for obtaining first and second input signals respectively,
a first and a second control transistors coupled to said first and said second switching transistors of said switching unit respectively, a first and a second comparators each including a first and a second input terminals and an output terminal, said first input terminal of said first comparator being coupled to said first control transistor via a first resistor, said second input terminal of said second comparator being coupled to said second control transistor via a second resistor, and
a first and a second detecting resistors coupled between said first input terminal of said first comparator and said second input terminal of said second comparator, to actuate either said first or said second comparator to output control signals.

8. The short-circuit detecting and protecting circuit as claimed in claim 7, wherein said first switching transistor is a pMOS, and said second switching transistor is an nMOS.

9. The short-circuit detecting and protecting circuit as claimed in claim 7 further comprising an overcurrent control means for switching off said short-circuit detecting and protecting circuit when receiving said output control signals from either said first or said second comparator.

10. The short-circuit detecting and protecting circuit as claimed in claim 9, wherein said overcurrent control means includes an OR gate coupled between said first and said second comparators.

11. The short-circuit detecting and protecting circuit as claimed in claim 10, wherein said overcurrent control means further includes a first and a second control circuits coupled to said first and said second switching transistors of said switching unit respectively, and coupled to said OR gate.

12. A short-circuit detecting and protecting circuit comprising:
a first detecting circuit including a first and a second input terminals for obtaining first and second input signals respectively,
a second detecting circuit including a first and a second input terminals for obtaining third and fourth input signals respectively, and
a load coupled between said first and said second detecting circuits.

13. The short-circuit detecting and protecting circuit as claimed in claim 12, wherein said first and said second input signals of said first detecting circuit are in phase, and said third and said fourth input signals of said second detecting circuit are in phase.

14. The short-circuit detecting and protecting circuit as claimed in claim 12, wherein either said first or said second input signal of said first detecting circuit is opposite in phase to either said third or said fourth input signal of said second detecting circuit.
